(19) United States
(12) Patent Application Publication
(10) Pub. No.: US 2026/0020315 A1
(43) Pub. Date: Jan. 15, 2026

(54) TRANSISTOR WITH MODIFIED GATE STRUCTURE

(71) Applicant: Taiwan Semiconductor Manufacturing Company, Ltd., Hsinchu (TW)

(72) Inventors: Tzu Jung Tien, Hsinchu (TW); Cheung Cheng, Hsinchu (TW); Wen-Chih Chiang, Hsinchu (TW)

(21) Appl. No.: 18/770,754

(22) Filed: Jul. 12, 2024

(51) Int. Cl. H01L 29/423; H01L 21/762; H01L 29/417; H01L 29/78

(52) U.S. Cl. CPC H10D 64/514; H01L 21/76205; H01L 21/76224; H10D 30/62; H10D 30/6219; H10D 30/6729; H10D 30/6735

(57) ABSTRACT

The gate electrode of a transistor includes at least one region with a p-type work function and at least one region with an n-type work function. The regions are located over corners formed between isolation regions and an active region. The double hump effect is reduced, which provides higher operational frequencies.

### BACKGROUND

Integrated circuits are formed on a semiconductor wafer. Photolithographic patterning processes use ultraviolet light to transfer a desired mask pattern to a photoresist on a semiconductor wafer. Etching processes may then be used to transfer to the pattern to a layer below the photoresist. This process is repeated multiple times with different patterns to build different layers on the wafer substrate and make a useful device.

An integrated circuit is made of large numbers of transistors. A field-effect transistor is generally composed of a substrate on which an electrically conductive gate electrode controls the flow of current between a source electrode and a drain electrode. An electrically insulating gate dielectric layer separates the gate electrode from the source and drain electrodes. A semiconductor layer bridges the source and drain electrodes, and is in contact with the gate dielectric layer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a plan view showing a first example embodiment of a transistor structure, in accordance with some embodiments of the present disclosure. FIG. 1B is a Y-axis cross-sectional view along line B-B of FIG. 1A. FIG. 1C is an X-axis cross-sectional view along line C-C of FIG. 1A.

FIG. 2A is a plan view showing a second example embodiment of a transistor structure, in accordance with some embodiments of the present disclosure. FIG. 2B is a Y-axis cross-sectional view along line B-B of FIG. 2A. FIG. 2C is an X-axis cross-sectional view along line C-C of FIG. 2A.

FIG. 3A is a plan view showing a third example embodiment of a transistor structure, in accordance with some embodiments of the present disclosure. FIG. 3B is a Y-axis cross-sectional view along line B-B of FIG. 3A. FIG. 3C is an X-axis cross-sectional view along line C-C of FIG. 3A.

FIG. 4A is a plan view showing a fourth example embodiment of a transistor structure, in accordance with some embodiments of the present disclosure. FIG. 4B is a Y-axis cross-sectional view along line B-B of FIG. 4A. FIG. 4C is an X-axis cross-sectional view along line C-C of FIG. 4A.

FIG. 5A is a plan view showing a fifth example embodiment of a transistor structure, in accordance with some embodiments of the present disclosure. FIG. 5B is a Y-axis cross-sectional view along line B-B of FIG. 5A. FIG. 5C is an X-axis cross-sectional view along line C-C of FIG. 5A.

FIG. 6A is a plan view showing a sixth example embodiment of a transistor structure, in accordance with some embodiments of the present disclosure. FIG. 6B is a Y-axis cross-sectional view along line B-B of FIG. 6A. FIG. 6C is an X-axis cross-sectional view along line C-C of FIG. 6A.

FIG. 7A and FIG. 7B together form a flow chart illustrating a method for forming the transistor structure, in accordance with some embodiments. Various steps of this method are shown in FIGS. 8A-15.

FIG. 8A is a plan view of the substrate after etching trenches for one or more isolation regions to define an active region. FIG. 8B is a Y-axis cross-sectional view along line B-B of FIG. 8A.

FIG. 9A is a plan view of the substrate after forming one or more isolation regions to define an active region. FIG. 9B is a Y-axis cross-sectional view along line B-B of FIG. 9A.

FIG. 10A is a plan view of the substrate after formation of a gate dielectric layer. FIG. 10B is a Y-axis cross-sectional view along line B-B of FIG. 10A.

FIG. 10C is a plan view of the substrate after formation of a LOCOS structure that acts as both isolation region and gate dielectric layer. FIG. 10D is a Y-axis cross-sectional view along line D-D of FIG. 10C.

FIG. 11A is a plan view of the substrate after deposition of a gate precursor layer. FIG. 11B is a Y-axis cross-sectional view along line B-B of FIG. 11A.

FIG. 12A is a plan view of the substrate after partial doping of the gate precursor layer to form one or more first regions with a first work function. FIG. 12B is a Y-axis cross-sectional view along line B-B of FIG. 12A.

FIG. 13A is a plan view of the substrate after partial doping of the gate precursor layer to form one or more second regions with a second work function. FIG. 13B is a Y-axis cross-sectional view along line B-B of FIG. 13A.

FIG. 14A is a plan view of the substrate after formation of source/drain (S/D) electrodes. FIG. 14B is a Y-axis cross-sectional view along line B-B of FIG. 14A.

FIG. 15 is a perspective view of the substrate after a second insulating layer has been applied over a first insulating layer, and pads are formed in the second insulating layer to form a source terminal, a drain terminal, and a gate terminal, to form a transistor package.

FIG. 16 is a flow chart illustrating a method for forming a FinFET structure, in accordance with some embodiments of the present disclosure.

FIG. 17 is a perspective view of a FinFET with a three-dimensional structure, for illustrating one resulting structure of the method of FIG. 16.

FIG. 18 is a flow chart illustrating a method for forming a Gate-All-Around (GAA) transistor structure, in accordance with some embodiments of the present disclosure.

FIG. 19 is a perspective view of an intermediate stage from which the method of FIG. 18 begins.

FIG. 20A is a Y-axis cross-sectional view along line A-A of FIG. 19. FIG. 20B is an X-axis cross-sectional view along line B-B of FIG. 19. These figures illustrate the intermediate stage from which the method of FIG. 18 begins.

FIG. 21A is a Y-axis cross-sectional view along line A-A of FIG. 19. FIG. 21B is an X-axis cross-sectional view along line B-B of FIG. 19. A gate dielectric layer has been applied to the semiconductor layers.

FIG. 22A is a Y-axis cross-sectional view along line A-A of FIG. 19. FIG. 22B is an X-axis cross-sectional view along line B-B of FIG. 19. The gate electrode includes first regions and second regions, having different work functions.

FIG. 23 is a flow chart illustrating a method for using a transistor, in accordance with some embodiments of the present disclosure.

FIG. 24A is a graph of drain leakage current vs. drain voltage. The y-axis is logarithmic, while the y-axis is linear. This graph is for a transistor where the gate electrode is made of one material. FIG. 24B is a graph for a transistor where the gate electrode has first regions and second regions, having different work functions.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure relates to structures which are made up of different layers. When the terms “on” or “upon” are used with reference to two different layers (including the substrate), they indicate merely that one layer is on or upon the other layer. These terms do not require the two layers to directly contact each other, and permit other layers to be between the two layers. For example all layers of the structure can be considered to be “on” the substrate, even though they do not all directly contact the substrate. The term “directly” may be used to indicate two layers directly contact each other without any layers in between them. In addition, when referring to performing process steps to the substrate or upon the substrate, this should be construed as performing such steps to whatever layers may be present on the substrate as well, depending on the context.

The present disclosure relates to various methods and structures which are particularly useful in improving the performance of high-voltage and medium-voltage transistors. The active region of the transistor is defined by isolation regions. In transistors with narrow channel widths, depletion layers adjacent the isolation regions result in “corners” adjacent the semiconducting channel through which current flows. An undesirable side effect of this structure is a bimodal “double hump” in the drain current versus gate voltage (Id−Vg) curve when a back bias voltage (Vb) is applied. This occurs because the channel device threshold voltage (Vt1) is greater than the corner device threshold voltage (Vt2). In the present disclosure, a specified gate electrode structure is used to reduce this double hump effect.

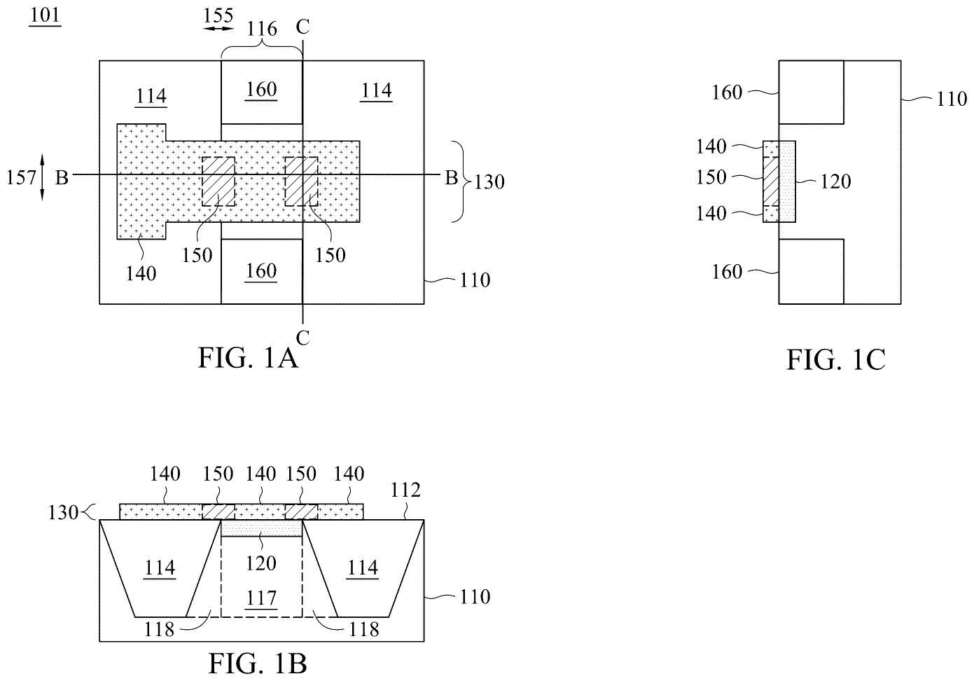

FIG. 1A is a plan view showing a first example embodiment of a transistor structure 101, in accordance with some embodiments of the present disclosure, and illustrating some features. FIG. 1B is a Y-axis cross-sectional view along line B-B of FIG. 1A. FIG. 1C is an X-axis cross-sectional view along line C-C of FIG. 1A. This transistor is a planar transistor or a thin-film transistor.

Referring to the figures together, the transistor 101 is formed on a substrate 110. Two isolation regions 114 are present, which may be, for example, shallow trench isolation (STI) regions or deep trench isolation (DTI) regions. The area between them is defined as an active region 116. It is noted that there may also be isolation regions in the X-axis (not illustrated), so that the active region is surrounded on all sides. As illustrated in FIG. 1B, a channel 117 is present between the isolation regions. Corners 118 are illustrated as being located below the isolation regions 114. The corners may also be considered as being adjacent the active region 116.

As better seen in FIG. 1B and FIG. 1C, a gate dielectric layer 120 is present, illustrated here as a layer below the upper surface 112 of the substrate. A gate electrode 130 is located over the gate dielectric layer 120. The gate electrode also extends over the isolation regions 114.

The gate electrode 130 is formed from one or more first regions 140 and one or more second regions 150. The first regions and the second regions have different work functions (i.e. p-type or n-type). Put another way, they have opposite work functions. If one region is an n-type region, then the other region is a p-type region. As illustrated in FIGS. 1A-1C, the gate electrode is formed from one first region 140 and two second regions 150. The first region 140 extends over both the isolation regions 114 and the active region 116. Put another way, the first region 140 extends over the corners 118. Similarly, each second region 150 extends over both an isolation region 114 and the active region 116. Put another way, each second region 150 extends over a corner 118. However, each second region does not extend over both isolation regions 114. In addition, the first region 140 surrounds the second regions 150.

The first region 140 has a generally rectangular shape, with enlarged dimensions at one end. Each second region 150 has a rectangular shape, with a length 155 and a width 157. In addition, here the first region 140 has an N-type work function, and the second regions 150 have a P-type work function. Because the majority of the surface area of the gate electrode 130 is N-type, this transistor will function as an N-type MOSFET (metal-oxide-semiconductor field-effect transistor), also abbreviated as NMOS. The shape of each second region 150 may independently vary as desired.

Source/drain (S/D) electrodes 160 are spaced apart from each other in the active region 116 on opposite sides of the gate dielectric layer 120 and the gate electrode 130.

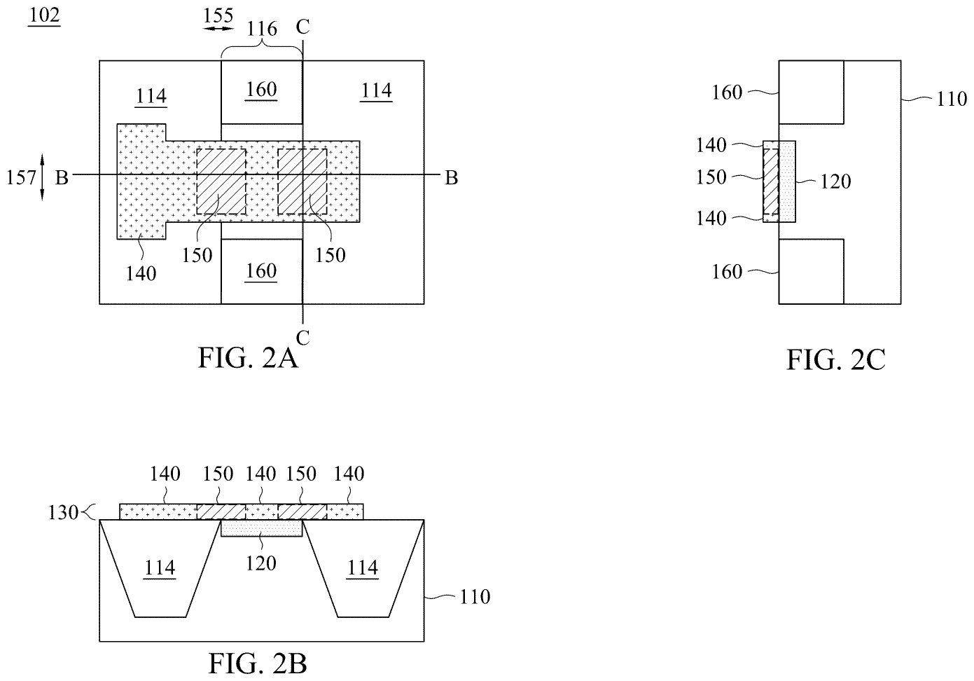

FIGS. 2A-2C are various views showing a second example embodiment of a transistor structure 102. In this example, the first region 140 has an N-type work function, and the second regions have a P-type work function. Here, the two second regions 150 have a length 155 and a width 157 which are greater (in each dimension) than the two second regions of FIGS. 1A-1C. Generally, changing the ratio of the surface areas of the first region(s) to the second region(s) permits control over the double hump effect by changing the sheet resistance Rs of the gate electrode (as will be further explained later).

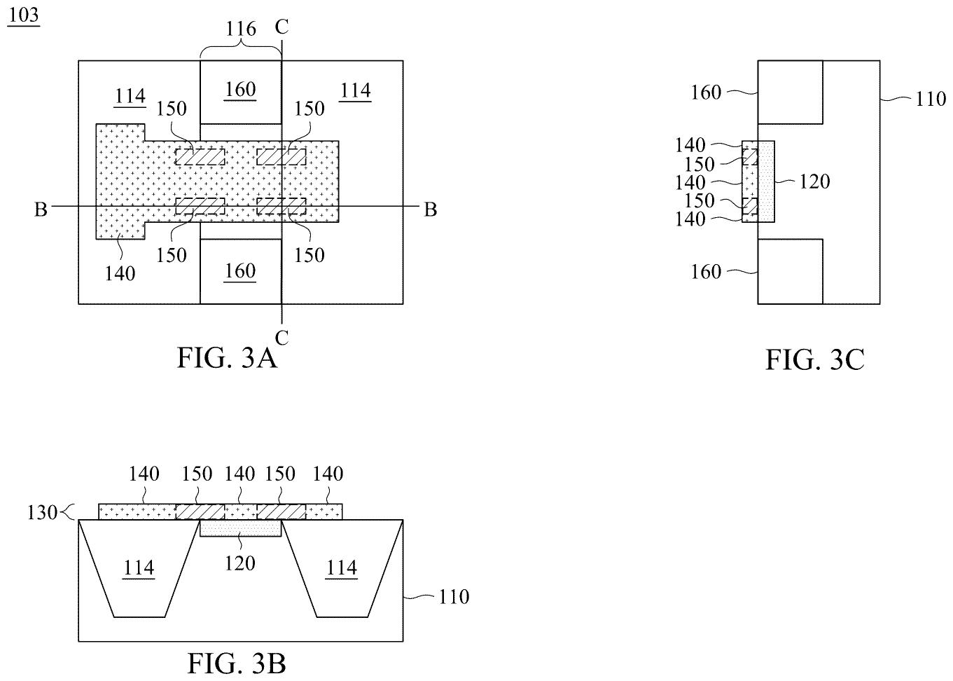

FIGS. 3A-3C are various views showing a third example embodiment of a transistor structure 103. In this example, the first region has an N-type work function, and the second regions have a P-type work function. This embodiment includes one first region 140 and four second regions 150. Again, each first region 140 and each second region 150 extends over both an isolation region 114 and the active region 116 (i.e. over a corner 118). Here, the second regions have a greater length 155 than width 157.

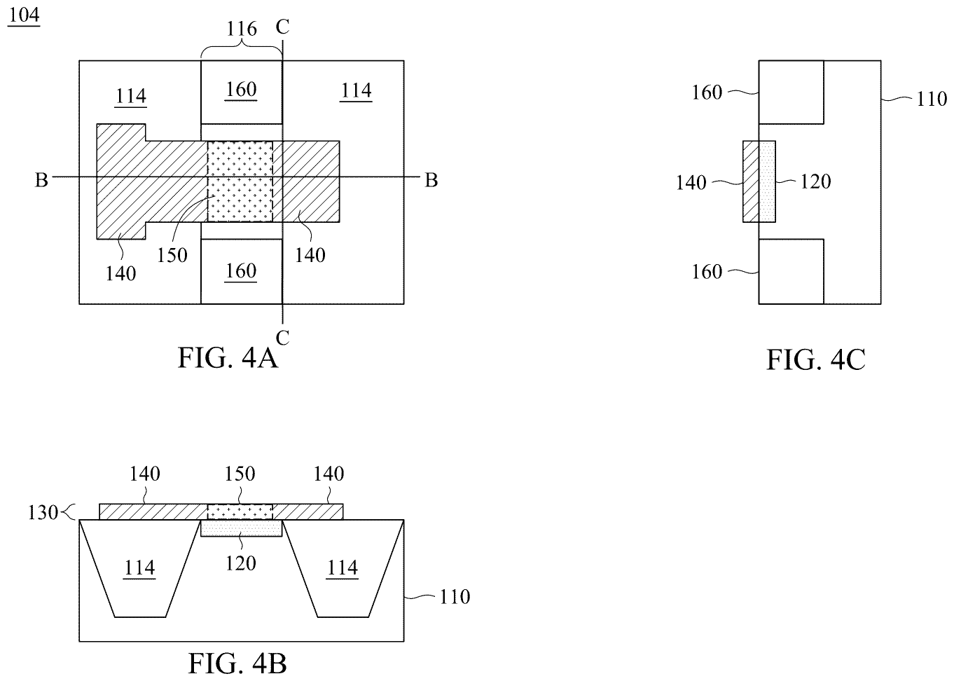

FIGS. 4A-4C are various views showing a fourth example embodiment of a transistor structure 104. This embodiment includes two first regions 140 and one second region 150. In addition, in this embodiment, the first regions have a P-type work function, and the second region has an N-type work function. Here, each first region 140 extends over both an isolation region 114 and the active region 116. The second region 150 is present only in the active region over the gate dielectric layer 120, and does not extend over an isolation region 114.

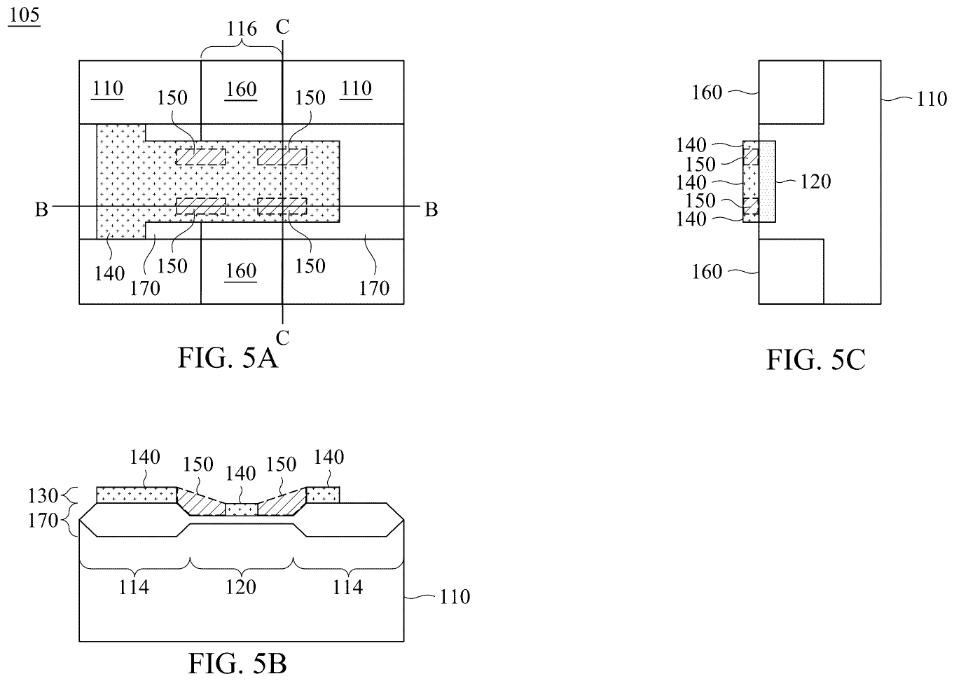

FIGS. 5A-5C are various views showing a fifth example embodiment of a transistor structure 105. In this example, a LOCal Oxidation of Silicon (LOCOS) structure 170 is present, which can generally be described as having a barbell shape where the ends have a greater height than the central portion. The ends can be considered the isolation regions 114, and the central portion can be considered the gate dielectric layer 120. The gate electrode 130 illustrated here has the same structure as shown in FIGS. 3A-3C. The first region has an N-type work function, and the second regions have a P-type work function. Again, each first region 140 and each second region 150 extends over both an isolation region 114 and the active region 116 (i.e. over a corner 118). Each first region extends over both isolation regions, while each second region extends over only one isolation region.

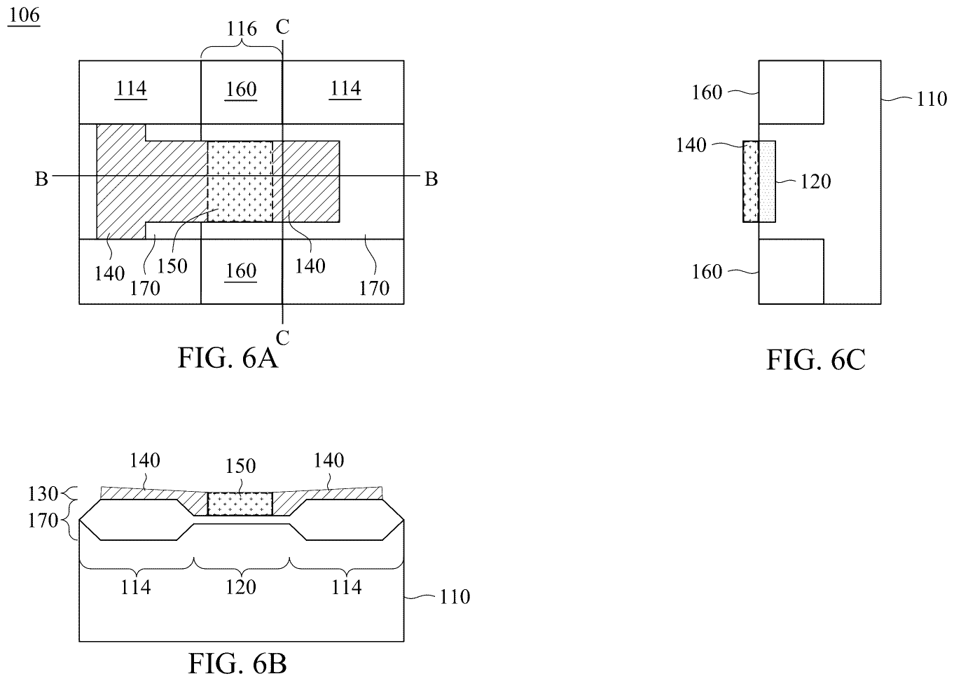

FIGS. 6A-6C are various views showing a sixth example embodiment of a transistor structure 106. In this example, the isolation regions 114 and the gate dielectric layer 120 are formed from a LOCOS structure 170. The gate electrode 130 illustrated here has the same structure as shown in FIGS. 4A-4C.

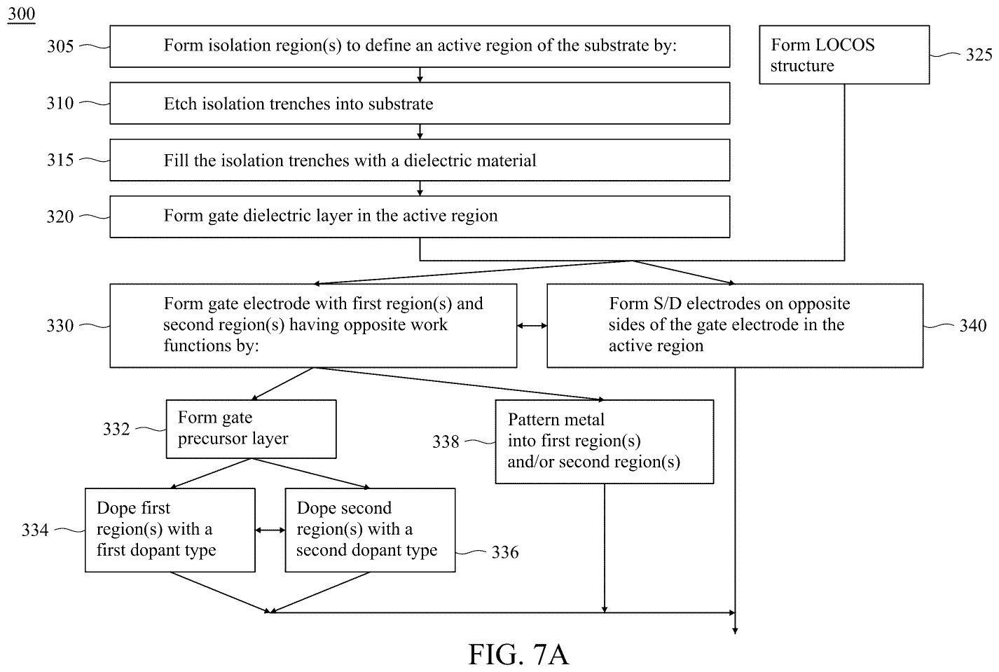

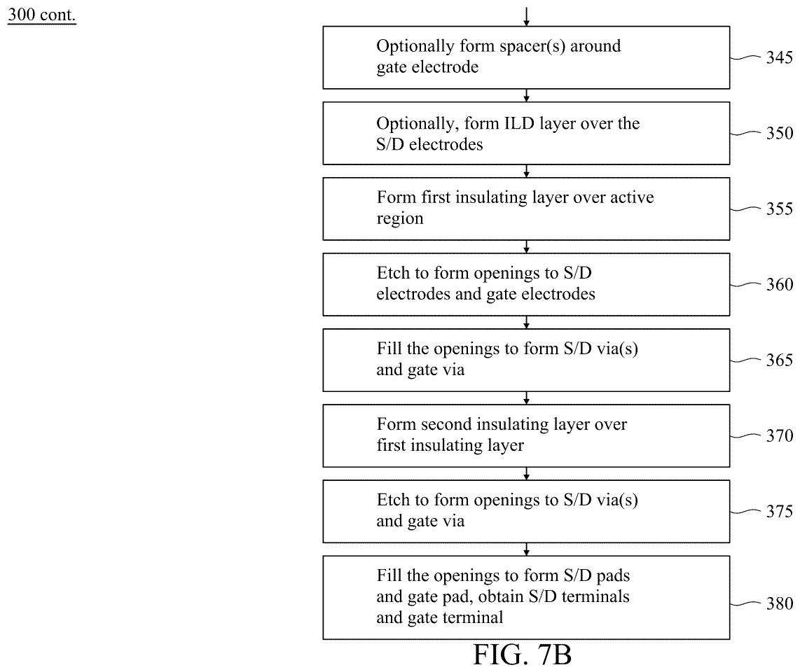

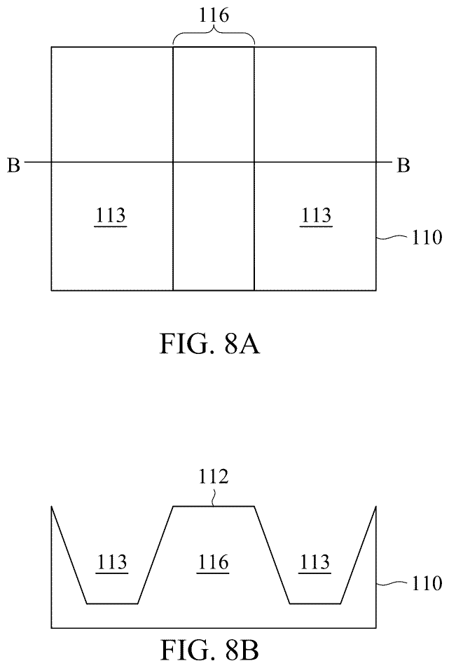

FIG. 7A and FIG. 7B together form a flow chart illustrating a first method 300 for making a transistor structure, in accordance with some embodiments. Some steps of the method are also illustrated in FIGS. 8A-15. These figures provide different views for better understanding. While the method steps are discussed below in terms of forming a single transistor structure, such discussion should also be broadly construed as applying to the concurrent formation of multiple transistors. It is noted that not all steps described in the flow chart are required.

Initially, FIG. 8A and FIG. 8B include a substrate 110 upon which the transistor will be formed. The substrate may be, for example, a wafer made of a semiconducting material. Such semiconductor materials can include silicon, for example in the form of crystalline Si. In alternative embodiments, the substrate can be made of other elementary semiconductors such as germanium, silicon carbide (SIC), silicon germanium, or silicon germanium carbide. The substrate may alternatively include a compound semiconductor such as gallium arsenide (GaAs), gallium phosphide, gallium carbide, indium arsenide (InAs), indium phosphide (InP), gallium arsenic phosphide, gallium indium phosphide, cadmium telluride, or cadmium sulfide. In particular embodiments, the substrate is silicon. The substrate includes an upper surface 112.

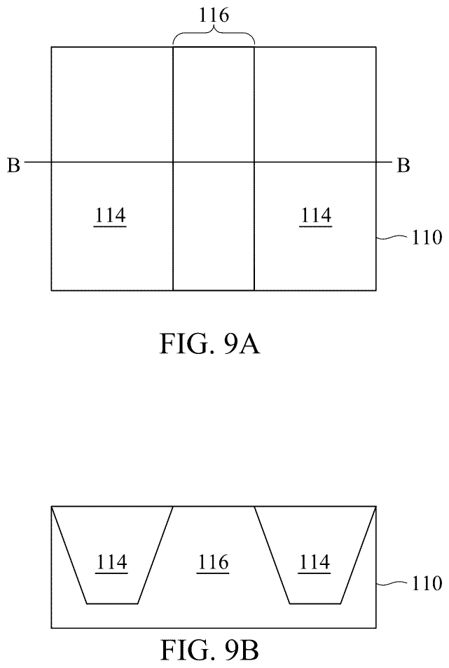

In step 305 of FIG. 7A and as illustrated in FIGS. 8A-9B, one or more isolation regions are formed in the substrate 110 to define an active region 116 of the substrate. The isolation regions may be, for example, shallow trench isolation (STI) regions or deep trench isolation (DTI) regions. The isolation regions are formed by patterning the substrate, etching isolation trenches 113 (see FIG. 8A and FIG. 8B) in step 310, and filling the trenches with a dielectric material (see FIG. 9A and FIG. 9B) in step 315 to obtain the isolation regions 114. The dielectric material in the isolation region is commonly silicon dioxide, although other dielectric materials can also be used such as undoped polysilicon, silicon oxide (e.g. SiO₂), silicon nitride, silicon oxynitride, fluoride-doped silicate glass, or other low-k dielectric material. The deposition can be done using physical vapor deposition (PVD) or chemical vapor deposition (CVD) or spin-on processes known in the art, or can be grown via oxidation. If desired, the dielectric material can be deposited to a level above that of the substrate upper surface 112, then recessed back down to the desired height.

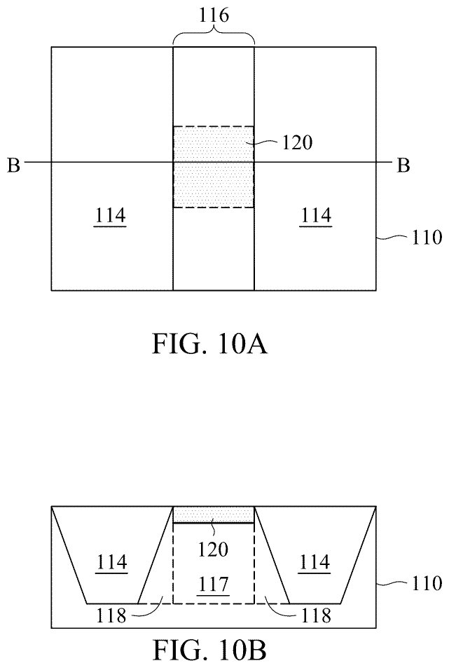

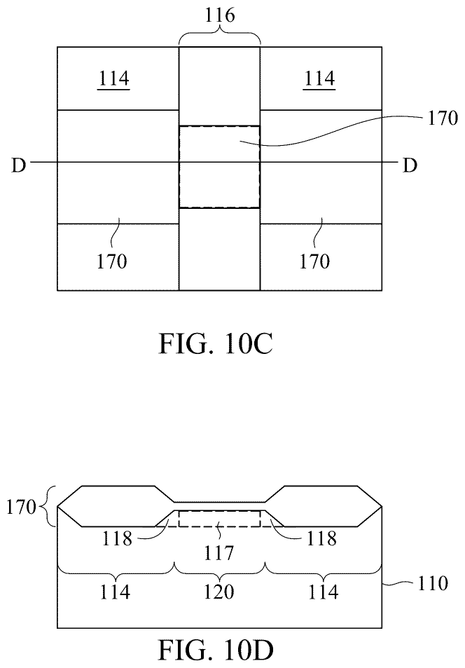

Next, in step 320 of FIG. 7A and as illustrated in FIG. 10A and FIG. 10B, a gate dielectric layer 120 is formed upon the substrate 110. Again, CVD, PVD, atomic layer deposition (ALD), ion implantation, or other suitable deposition process may be used to form the gate dielectric layer. Thermal oxidation may also be used. The gate dielectric layer may be made, for example, from silicon dioxide, silicon oxynitride (SiOₓN_{y}), SiN, HfO, doped HfO, or other high-k dielectric material. The gate dielectric layer is formed in the active region 116 between the isolation regions 114. For reference, the semiconducting channel 117 and the corners 118 are also illustrated.

Alternatively, a LOCOS structure may be formed in step 325 of FIG. 7A if desired. This may be done, for example, through thermal oxidation or other suitable means. The resulting structure is illustrated in FIG. 10C and FIG. 10D. The LOCOS structure 170 may be considered as providing both the isolation regions 114 and the gate dielectric layer 120, and as defining the active region 116.

Next, in step 330 of FIG. 7A, a gate electrode is formed which includes one or more first regions and one or more second regions. The first region(s) and the second region(s) have opposite work functions. The “work function” refers to whether the region is made/doped with a p-type material or an n-type material.

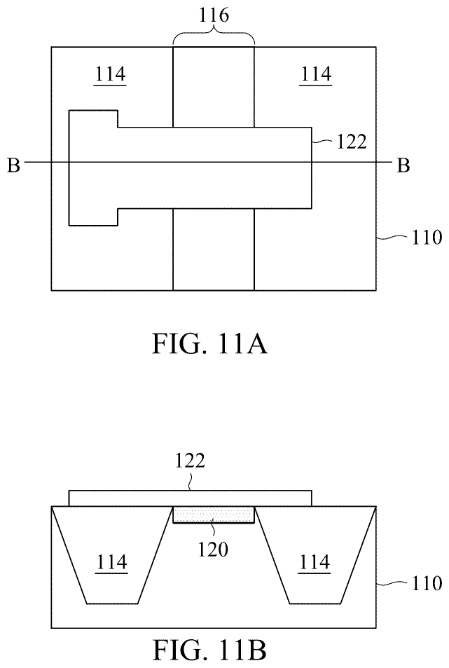

In one method for forming the gate electrode, in step 332 of FIG. 7A and as illustrated in FIG. 11A and FIG. 11B, a gate precursor layer 122 is formed. The gate precursor layer extends over both isolation regions 114 and the active region 116. This may be done by CVD, PVD, or other suitable process. In particular embodiments, the gate precursor layer is made of polysilicon.

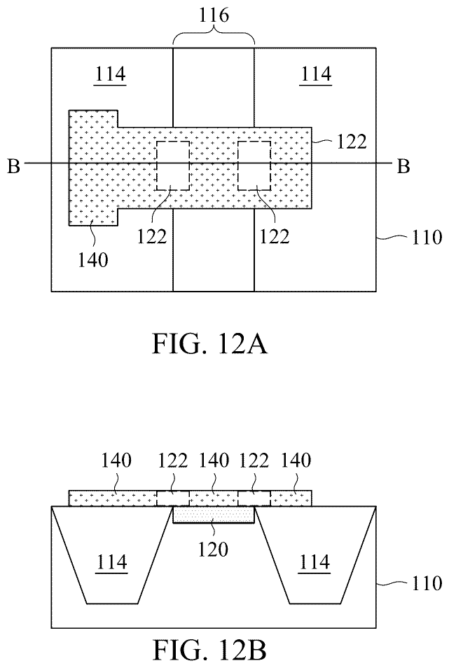

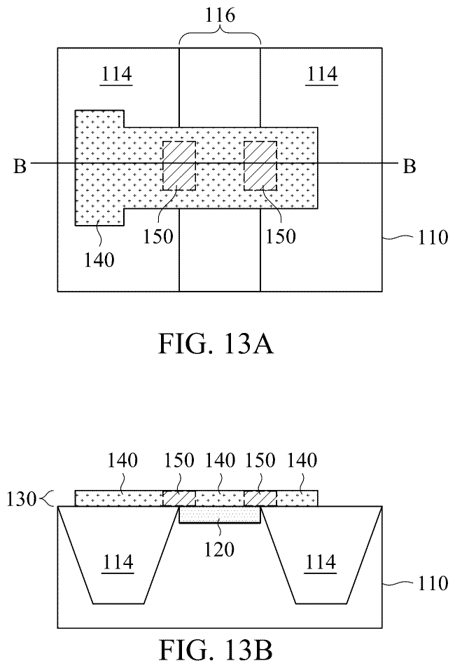

Then, in step 334 of FIG. 7A and as illustrated in FIG. 12A and FIG. 12B, portions of the gate precursor layer 122 are doped with a first dopant type to obtain one or more first region(s) 140. Then, in step 336 of FIG. 7A and as illustrated in FIG. 13A and FIG. 13B, portions of the gate precursor layer 122 are doped with a second dopant type to obtain one or more second region(s) 150.

The doping may be performed by ion implantation or other suitable methods. Briefly, in ion implantation, an ion implanter is used to implant atoms into a silicon crystal lattice, modifying the conductivity of the lattice in the implanted location. An ion implanter generally includes an ion source, a beam line, and a process chamber. The ion source produces the desired ions. The beam line organizes the ions into a beam having high purity in terms of ion mass, energy, and species. A mask, such as a patterned photoresist layer or a hard mask layer, is used to expose desired regions of the substrate. The ion beam is then used to irradiate the semiconducting wafer substrate in a process chamber. The ion beam strikes the exposed regions on the wafer substrate, and the ions can be implanted into the substrate as dopants at desired depths. Alternatively, the substrate can be partially etched, followed by blanket deposition of the dopant, following by annealing in which the dopant reacts with the underlying exposed silicon.

The first dopant type and the second dopant type are different from each other in their charge. If the first dopant type is an n-type dopant, then the second dopant type is a p-type dopant, or vice versa. As illustrated here, the first dopant type is n-type, and the second dopant type is p-type.

Common n-type dopants for silicon substrates may include nitrogen (N), phosphorus (P), arsenic (As), bismuth (Bi), or tantalum (Ta). Common p-type dopants for silicon substrates may include boron (B), aluminum (Al), gallium (Ga), or indium (In). Different dopants may be used for different substrates. For example, in gallium arsenide, n-type dopants may include tin (Sn), silicon (Si), or titanium (Ti). In gallium arsenide, p-type dopants may include beryllium (Be), zinc (Zn), chromium (Cr), silicon (Si), or germanium (Ge). In gallium phosphide, n-type dopants may include tellurium (Te), selenium (Se), sulfur(S), or oxygen (O). In gallium phosphide, p-type dopants may include zinc (Zn), magnesium (Mg), or tin (Sn). In cadmium telluride, n-type dopants may include indium (In), aluminum (AI), fluorine (F), chlorine (CI), bromine (Br), or iodine (I). In cadmium telluride, p-type dopants may include (P), lithium (Li), or sodium (Na). In cadmium sulfide, n-type dopants may include (Ga), fluorine (F), chlorine (CI), bromine (Br), or iodine (I). In cadmium sulfide, p-type dopants may include lithium (Li) or sodium (Na).

Alternatively, as described in step 338 of FIG. 7A, the first region(s) and/or the second region(s) may be formed by deposition and patterning of a metal layer. Suitable metals may include, for example, W, TIN, TiAl, Pt, Co, Rh, Pd, Ti, or Ta. Suitable processes such as CVD, PVD, ALD, or other deposition techniques may be used. As illustrated in FIG. 7A, the first region(s) and the second region(s) may be formed in any order, using either method.

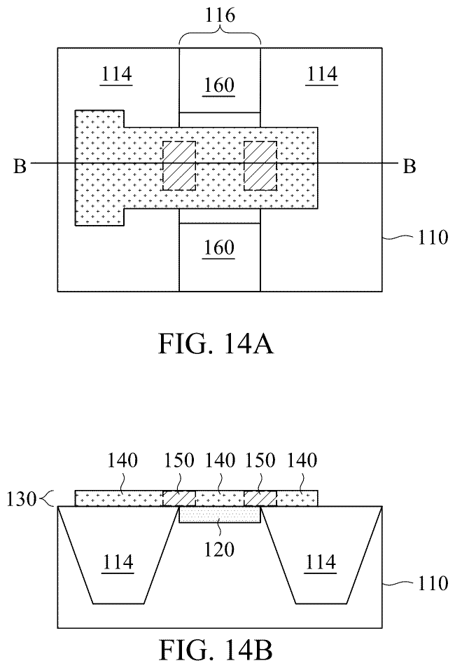

Next, in step 340 of FIG. 7A and as illustrated in FIG. 14A and FIG. 14B, source/drain (S/D) electrodes 160 are formed in the active region 116. As indicated here, the S/D electrodes 160 are formed on opposite sides of the gate electrode 130. They may be formed using ion implantation or other suitable methods to dope the silicon substrate, or by patterning and deposition of suitable metals. As illustrated in FIG. 7A, the gate electrode 130 and the S/D electrodes 160 may be formed in either order. The transistor of FIGS. 1A-1C is thus formed.

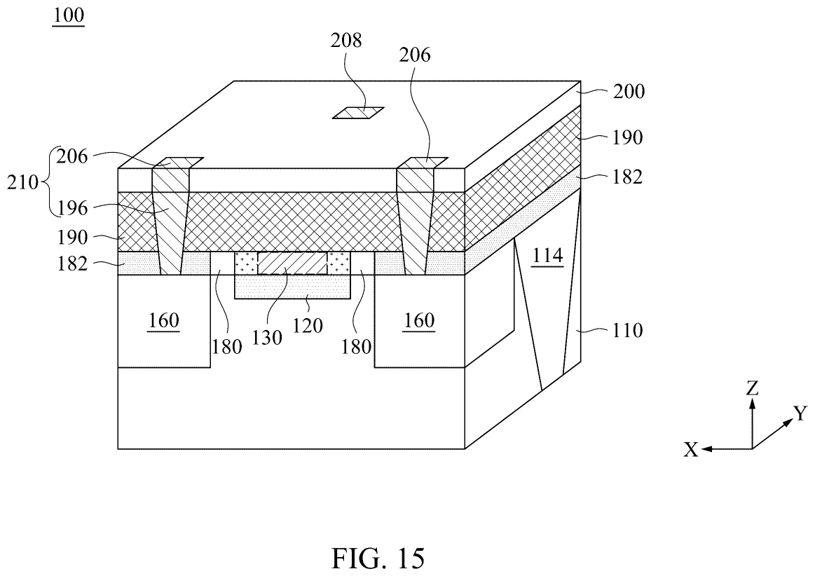

Further processing may occur to package the transistor. Referring now to FIG. 7B and FIG. 15, in optional step 345, at least one gate spacer 180 may be formed upon the sidewalls of the gate electrode 130. The gate spacer(s) are vertically oriented, and have a relatively narrow width. The gate spacers can be made from a dielectric material for electrical isolation of the gate electrode. In particular embodiments, the gate spacer(s) are silicon nitride (SIN) or silicon dioxide (SiO₂). The gate spacer(s) can be made by CVD, PVD, ALD, or other deposition technique.

Next, in optional step 350 of FIG. 7B, an interlayer dielectric (ILD) material can be applied over the S/D electrodes 160 to form ILD regions 182. The ILD regions electrically separate the source/drain electrodes 160 from the gate electrode 130. The ILD regions may be formed from any dielectric material, and do not need to be a high-k dielectric material. The ILD material can be deposited using any appropriate method, for example CVD.

Next, in step 355 of FIG. 7B, a first insulating layer 190 is formed over the active region, including the S/D electrodes 160 and the gate electrode 130. This layer may be formed using processes such as PVD, CVD, SACVD, or other suitable deposition process. The material for the first insulating layer may be silicon or other suitable dielectric material (e.g. silicon dioxide).

Then, in step 360 of FIG. 7B and as illustrated in FIG. 15, etching is performed to form openings that extend through the first insulating layer 190 and the ILD regions 182 to the S/D electrodes 160 and the gate electrode 130. In step 365, the openings are then filled with an electrically conductive material to form source/drain vias 196 and a gate via (not visible). The first insulating layer may also be considered to be an interconnect layer that permit various components to communicate with each other, or a redistribution layer (RDL).

The vias 196 themselves may be sufficient to act as a terminal (i.e. a source terminal, a drain terminal, and a gate terminal) for further processing steps. If a larger contact footprint is desired, these steps can be repeated.

For example, in step 370 of FIG. 7B and as illustrated in FIG. 15, a second insulating layer 200 is formed upon the first insulating layer 190. Then, in step 375 of FIG. 7B, etching is performed to form openings that extend through the second insulating layer 200 to the vias 196 in the first insulating layer. In step 380, the openings are then filled with an electrically conductive material to form source/drain pads 206 and a gate pad 208. S/D terminals 210 are formed from the combination of an S/D via 196 and an S/D pad 206. A gate terminal is formed from the combination of a gate via (not visible) and a gate pad 208. It is noted that the gate terminal is separated in the direction of the Y-axis from the S/D terminals 210.

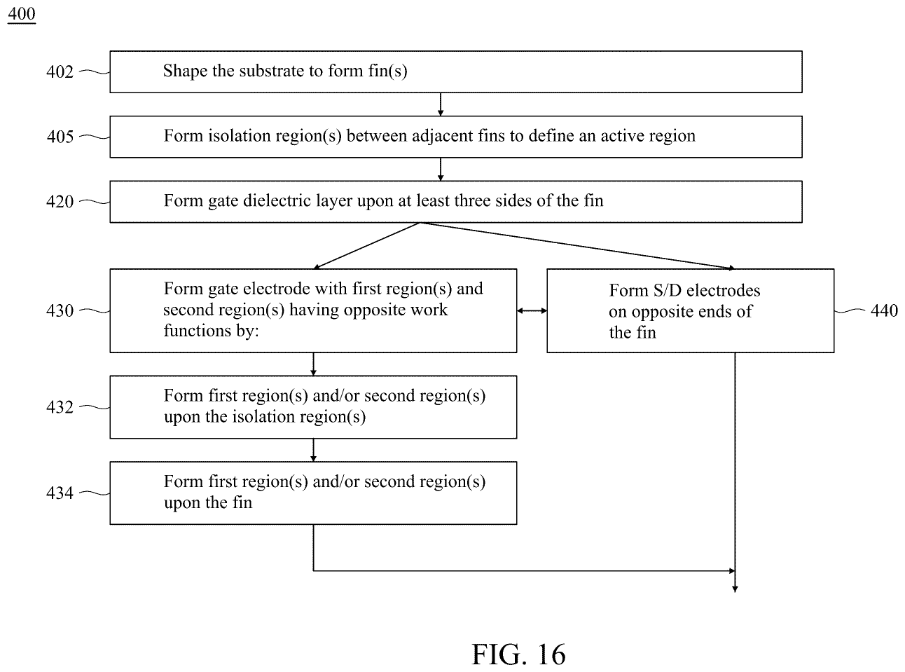

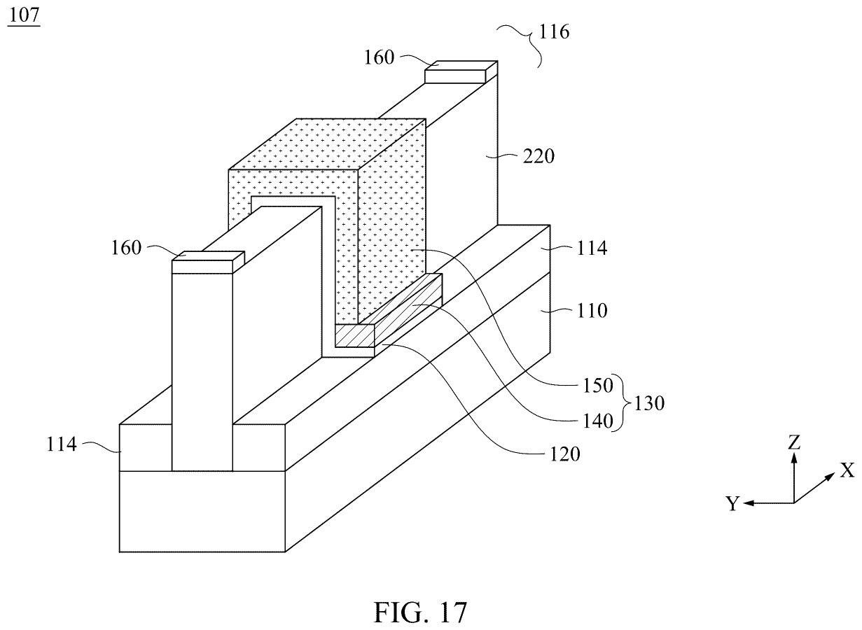

FIG. 16 is a flow chart illustrating a method 400 for making a FinFET (fin field effect transistor) 107 with a three-dimensional structure, in accordance with some embodiments. The method is described with reference to the final structure illustrated in FIG. 17, for better understanding. These figures provide different views for better understanding. Again, the method steps are discussed below in terms of forming a single transistor structure, but such discussion should also be broadly construed as applying to the concurrent formation of multiple transistors.

Initially, in step 402, the substrate 110 is shaped to form one or more fins 220. Typically, one or more hardmask layers is/are applied to the substrate. Mandrels are then formed upon the hardmask layer(s) over the substrate. This can be done by depositing a mandrel material layer, forming a photoresist layer upon the mandrel material layer, exposing the photoresist to radiation and developing the photoresist layer to form a mandrel pattern, and then etching the mandrel material layer to form the mandrels. If desired, the mandrels are then used as a mask, and etching is performed through the hardmask layer(s) and into the substrate is performed to form the fins. Alternatively, in a process known as self-aligned double patterning (SADP), spacers are formed on the sidewalls of the mandrels, and the mandrels are then removed. The spacers are then used as a mask, and etching is performed through the hardmask layer(s) and into the substrate is performed to form the fins. Self-aligned quadruple patterning (SAQP) is a similar process, and can also be used to form the fins.

Many of the following steps are the same as those in the method of FIG. 7A, suitably modified for a FinFET. In step 405, isolation regions 114 are formed between adjacent fins, to define an active region 116. In step 420 a gate dielectric layer 120 is formed upon three sides of the fin. In step 430, a gate electrode 130 is formed which includes one or more first regions 140 and one or more second regions 150. The first region(s) and the second region(s) have opposite work functions. As illustrated in FIG. 15, the gate electrode includes two first regions 140 upon the isolation regions 114 and one second region 150 upon the fin 220. However, this can vary as desired, as illustrated in the various embodiments of FIGS. 1A-6C (suitably modified to apply to a FinFET). This may be done in two separate steps, as indicated in steps 432, 434 of FIG. 16. Then, in step 440, S/D electrodes 160 are formed on opposite ends of the fin, on opposite sides of the gate electrode 130. The resulting structure is shown in FIG. 17. Process steps 345-380 of FIG. 7B may also be performed to package the FinFET.

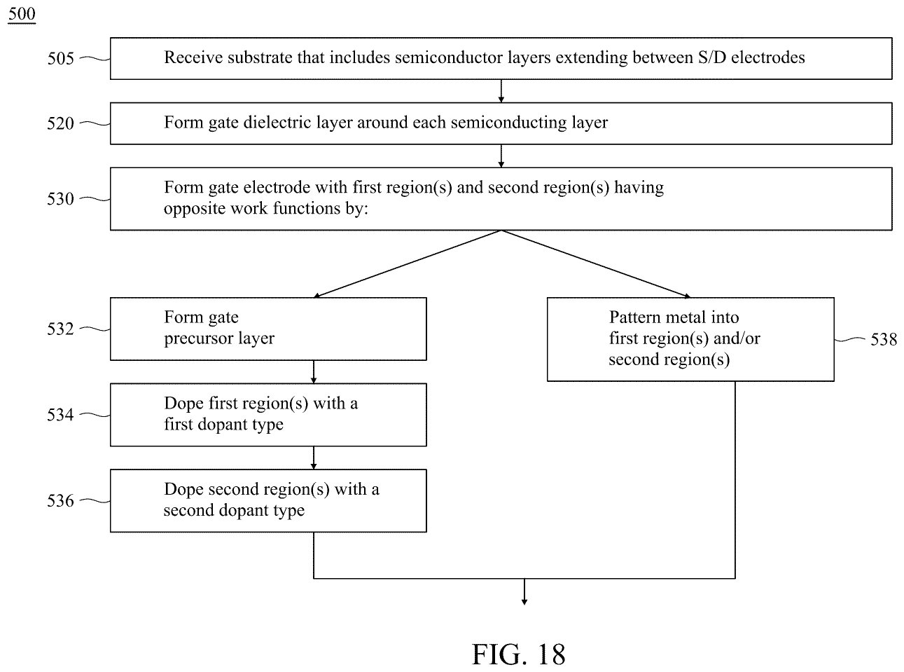

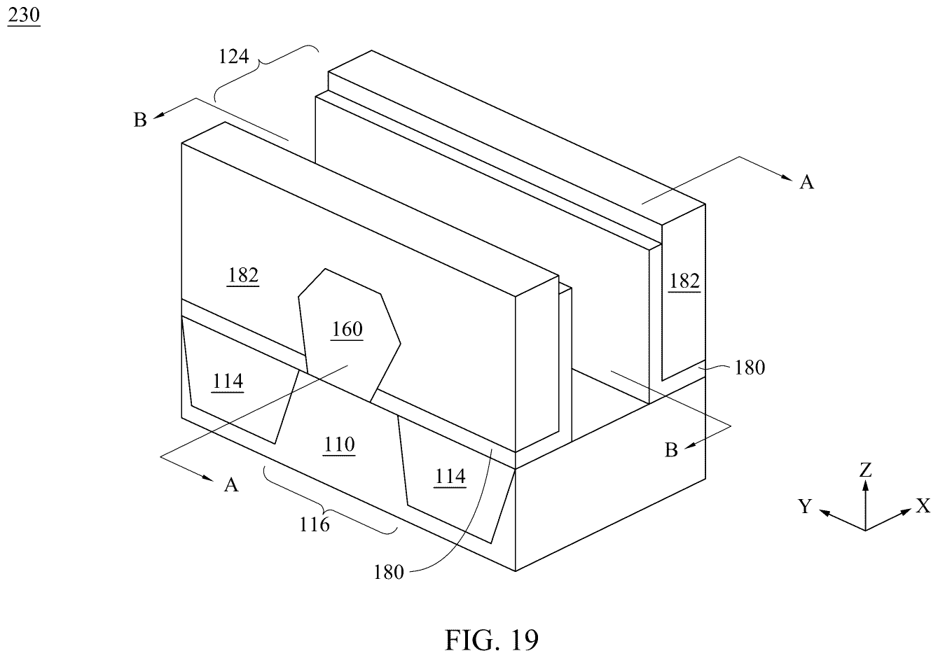

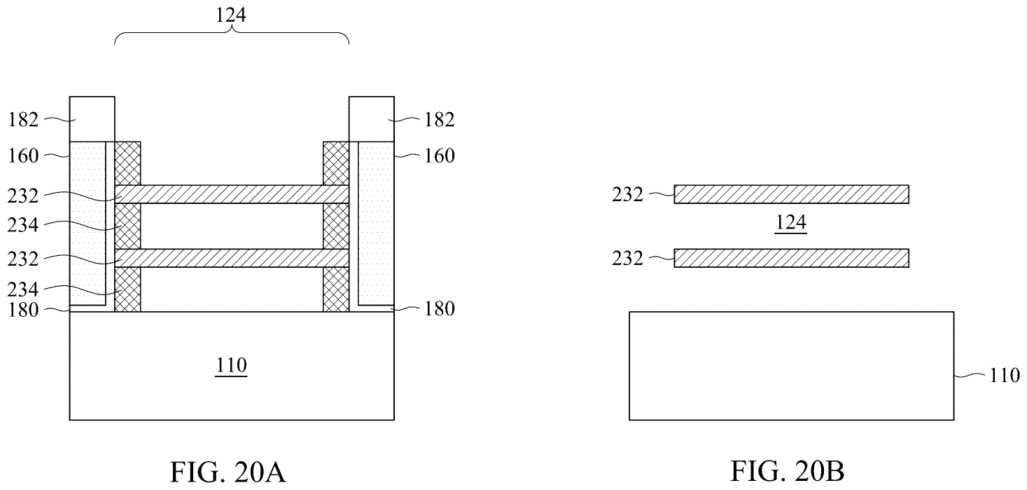

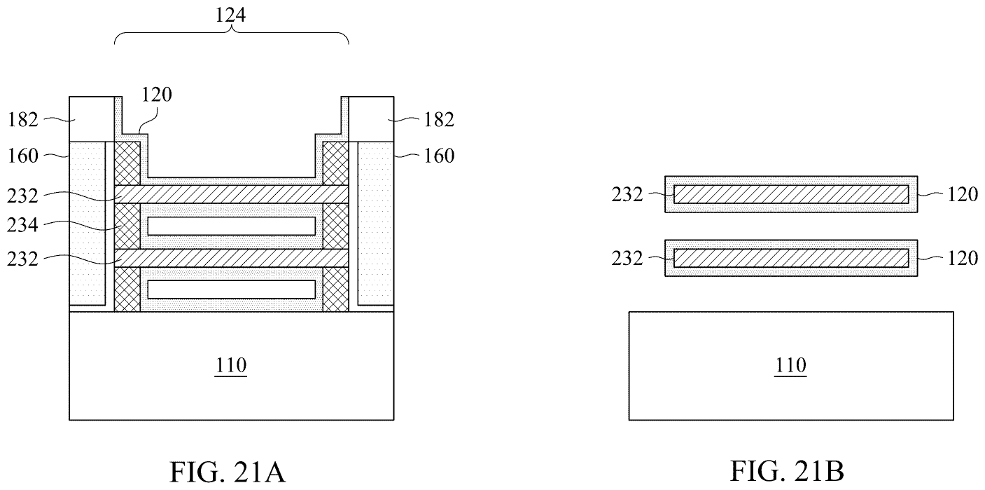

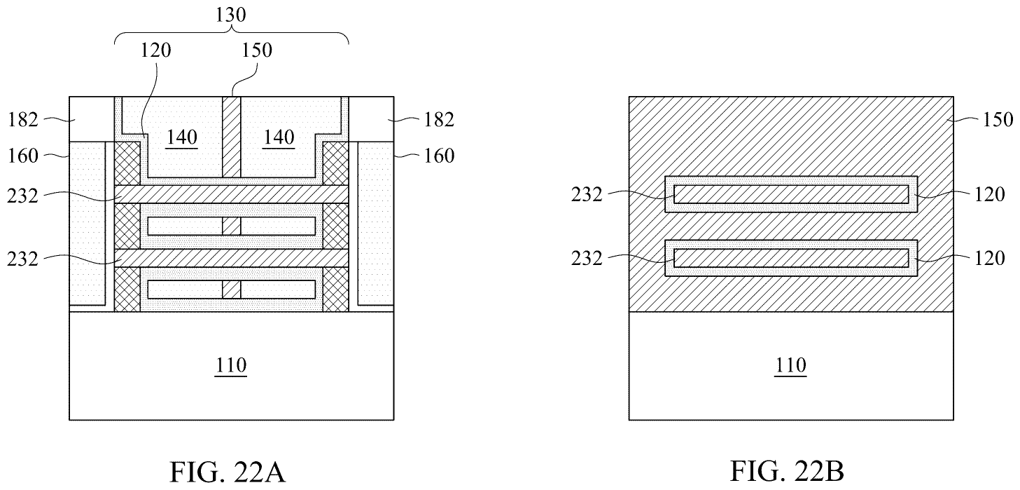

FIG. 18 is a flow chart illustrating a method 500 for making a Gate-All-Around (GAA) transistor 108, in accordance with some embodiments. Some steps of the method are also illustrated in FIGS. 19-22B for better understanding. Again, the method steps are discussed below in terms of forming a single transistor structure, but such discussion should also be broadly construed as applying to the concurrent formation of multiple transistors. FIG. 20A, FIG. 21A, and FIG. 22A are cross-sectional views through line A-A of FIG. 19. FIG. 20B, FIG. 21B, and FIG. 22B are cross-sectional views through line B-B of FIG. 19.

Initially, in step 505 of FIG. 18, a substrate is received that includes semiconductor layers extending between S/D electrodes. FIG. 19 is a perspective view of an intermediate stage 230. FIG. 20A is a Y-axis cross-sectional view along line A-A of FIG. 19. FIG. 20B is an X-axis cross-sectional view along line B-B of FIG. 19.

Referring first to FIG. 19, isolation regions 114 are present in the substrate 110. An S/D electrode 160 is visible in the active region 116. The S/D electrodes (only one visible) are each surrounded by an ILD region 182. Dielectric spacers 180 separate the ILD regions 182 from the gate region 124. Referring now to FIG. 20A, semiconducting layers 232 extend between the S/D electrodes 160. Inner spacers 234 are present between the semiconducting layers 232. Each individual semiconducting layer could be considered an active region, or the combination of semiconducting layers could be considered an active region. The gate region 124 is shown as empty.

The isolation regions 114 of the intermediate stage may be formed as previously described above, by etching trenches into the substrate and filling the trenches with a dielectric material to form an active region between the isolation regions. Semiconducting layers and sacrificial layers are then alternated to form a semiconducting stack in the active region. A dummy gate stack is then formed over a portion of the semiconducting stack. A dielectric spacer layer is applied over the dummy gate stack, the semiconducting stack, and the isolation regions. The dielectric spacer layer is selectively etched to expose the various layers of the semiconducting stack in the direction perpendicular to the dummy gate stack. Recesses are then formed in the sacrificial layers, and the recesses are then filled to form the inner spacers 234. S/D electrodes 160 are then formed on opposite sides of the dummy gate stack, adjacent to the exposed layers of the semiconducting stack. The S/D electrodes are separated from the dummy gate stack by the dielectric spacer layer 180. ILD regions 182 are then applied over the S/D electrodes. The portion of the dielectric spacer layer over the dummy gate stack is then removed, and the dummy gate stack is then removed. The sacrificial layers are then removed. The resulting structure is shown in FIG. 19 and FIG. 20A and FIG. 20B.

Continuing, in step 520 of FIG. 18 and as illustrated in FIG. 21A and FIG. 21B, a gate dielectric layer 120 is formed around each semiconducting layer 232. The gate dielectric layer can be made of any dielectric material as previously described. This may be done using any deposition process as previously described. It is noted that the gate dielectric layer 120 is also present on the surfaces of the inner spacers 234 and the ILD regions 182, which are also dielectric materials, and thus this deposition is acceptable.

Continuing, in step 530 of FIG. 18 and as illustrated in FIG. 22A and FIG. 22B, a gate electrode 130 is formed which includes one or more first regions 140 and one or more second regions 150. The first region(s) and the second region(s) have opposite work functions. In one method for forming the gate electrode, in step 532 a gate precursor layer is formed. Then, in step 534, portions of the gate precursor layer are doped with a first dopant type to obtain one or more first region(s) 140. Then, in step 536, portions of the gate precursor layer 122 are doped with a second dopant type to obtain one or more second region(s) 150. Alternatively, in step 538, a metal is deposited and patterned to form the first region(s) and/or the second region(s). Process steps 345-380 of FIG. 7B may also be performed to package the GAA transistor.

The transistors and methods of the present disclosure include several different dielectric structures. Such dielectric structures can generally be made from any suitable combination of dielectric materials, although the characteristics of any particular layer may also be further defined. Examples of dielectric materials may include silicon dioxide (SiO₂), silicon nitride (Si₃N₄), silicon carbide (SiC), hafnium dioxide (HfO₂), zirconium dioxide (ZrO₂), aluminum oxide (Al₂O₃), silicon oxynitride (SiOₓN_{y}), hafnium oxynitride (HfOₓN_{y}) or zirconium oxynitride (ZrOₓN_{y}), or hafnium silicates (ZrSiₓO_{y}) or zirconium silicates (ZrSiₓO_{y}) or silicon carboxynitride (SiCₓO_{y}N_{z}), or hexagonal boron nitride (hBN). Other dielectric materials may include tantalum oxide (Ta₂O₅), nitrides such as silicon nitride, polysilicon, phosphosilicate glass (PSG), fluorosilicate glass (FSG), undoped silicate glass (USG), high-stress undoped silicate glass (HSUSG), and borosilicate glass (BSG).

It is also noted that certain conventional steps are not expressly described in the discussion above. For example, a pattern/structure may be formed in a given layer by applying a photoresist layer, patterning the photoresist layer, developing the photoresist layer, and then etching.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the photoresist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90° C. to about 110° C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern. One example of a common developer is aqueous tetramethylammonium hydroxide (TMAH). Generally, any suitable developer may be used. Sometimes, a post develop bake or “hard bake” may be performed to stabilize the photoresist pattern after development, for optimum performance in subsequent steps.

Continuing, portions of the layer below the patterned photoresist layer are now exposed. Etching transfers the photoresist pattern to the layer below the patterned photoresist layer. After use, the patterned photoresist layer can be removed, for example, using various solvents such as N-methyl-pyrrolidone (NMP) or alkaline media or other strippers at elevated temperatures, or by dry etching using oxygen plasma.

Generally, any etching step described herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

Planarization of a surface may be performed, for example, using a chemical mechanical polishing (CMP) process. Generally, CMP is performed using a rotating platen to which a polishing pad is attached. The substrate is attached to a rotating carrier. A slurry or solution containing various chemicals and abrasives is dispensed onto the polishing pad or the wafer substrate. During polishing, both the polishing pad and the carrier rotate, and this induces mechanical and chemical effects on the surface of the wafer substrate and/or the top layer thereon, removing undesired materials and creating a highly level surface. A post-CMP cleaning step is then carried out using rotating scrubber brushes along with a washing fluid to clean one or both sides of the wafer substrate.

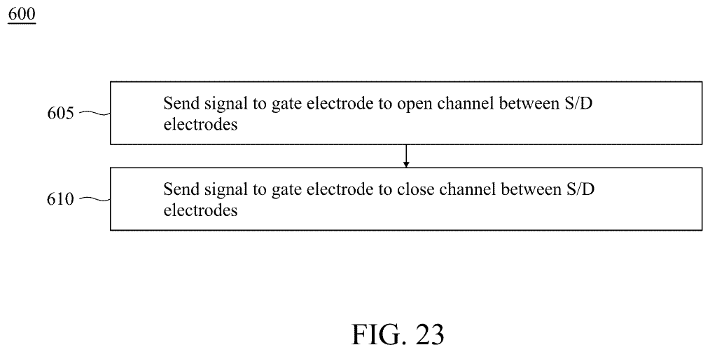

FIG. 23 is a flow chart illustrating a method 600 for operating a transistor, in accordance with some embodiments. The method steps are discussed below in terms of using a single transistor, and should also be broadly construed as applying to the concurrent use of multiple transistors. Reference is also made to the structure of FIGS. 1A-1C.

In step 605 of FIG. 23, a signal is sent to a gate electrode 130. Typically, a voltage signal is sent, either in the form of an increased voltage or a decreased voltage (depending on how the gate electrode is operated). This opens a channel 117 between the S/D electrodes 160, which permits current to flow between them. In step 610 of FIG. 23, a different signal is sent to the gate electrode 130 to close the channel 117.

The transistors of the present disclosure have a combination of advantages. The transistor does not exhibit the double hump phenomenon in the drain current vs. gate voltage curve. This is because the composite work function provided by the combination of first region(s) and second regions(s) in the gate electrode increases the corner device resistance. Device size can be reduced as well. Robust devices with higher operational frequency can be obtained as well.

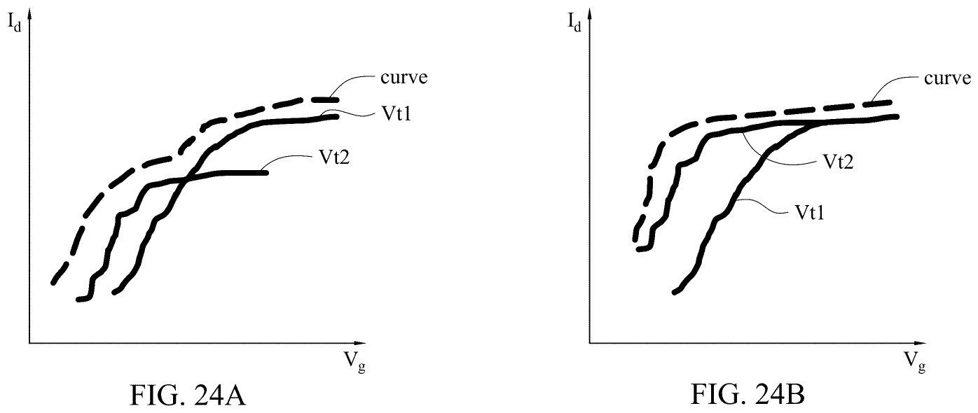

For example, if the Id−Vg curve is measured at various offset bias voltages (Vb), a transistor with a gate electrode made entirely from a single material will produce a graph of drain leakage current vs. drain voltage as illustrated in FIG. 24A. A double hump is visible in the curve. The curve is the composite of two smaller curves, the channel device threshold voltage curve (Vt1) and the corner device threshold voltage (Vt2).

In contrast, a transistor made with a gate electrode that was made from two different materials with opposite work functions will exhibit a curve as shown in FIG. 24B. There is no double hump effect in this curve. Compared to FIG. 24A, in this example, the Vt2 curve moved upwards while the Vt1 curve remained in place.

The transistors of the present disclosure are especially useful for high voltage, medium voltage, and low voltage devices on chips. High voltage devices typically operate from about 12 volts (V) to about 28V. Medium voltage devices typically operate from about 3V to about 9V. Low voltage devices usually operate below 1V.

Additional processing steps may be performed to fabricate a semiconductor device or integrated circuit with additional structures. Examples of such steps may include ion implantation, deposition of other materials, etching, etc.

The semiconductor devices might be used in various applications such as BCD (Bipolar-CMOS-DMOS) circuits for driving discrete high voltage components; drivers for LCD, OLED, AMOLED, or QLED display panels; image sensors that can be used in systems such as mobile telephones, facial recognition systems, or as motion sensors for automotive applications, security applications, energy efficiency, etc.; power management devices that control the flow and direction of electrical power; and/or image signal processors (ISP).

Some embodiments of the present disclosure thus relate to methods for forming a transistor. Isolation regions are formed in a substrate on opposite sides of an active region. A gate dielectric layer is formed between the isolation regions in the active region. A gate electrode is formed over the gate dielectric layer. The gate electrode comprises one or more first regions with a first work function and one or more second regions with a second opposite work function. Source/drain (S/D) electrodes are formed on opposite sides of the gate dielectric layer in the active region.

Also disclosed in various embodiments are transistors that comprise a substrate with one or more active regions extending between two S/D electrodes. Isolation regions are present on opposite sides of the active region. A gate dielectric layer is present over the one or more active regions between the two S/D electrodes. A gate electrode is present over the gate dielectric layer. The gate electrode comprises one or more first regions with a first work function and one or more second regions with a second opposite work function. The transistor could be a planar transistor, a FinFET, or a GAA transistor.

Some other embodiments of the present disclosure relate to a transistor that comprises a substrate. The substrate comprises a fin that extends between two S/D electrodes. Two isolation regions are present on opposite sides of the fin. A gate dielectric layer is present upon at least three sides of the fin between the two S/D regions. A gate electrode is located upon the gate dielectric layer. The gate electrode comprises one or more first regions with a first work function and one or more second regions with a second opposite work function. In some embodiments, the one or more first regions and/or the one or more second regions are located over corners formed between isolation regions and an active region.

Also disclosed are semiconductor devices comprising one or more transistors having the structures described above. The transistor(s) may be packaged, for example with ILD regions and insulating layer(s) as described above, with vias/terminals extending through the insulating layer(s).

Also disclosed are methods for operating a transistor. A voltage signal to a gate electrode is changed to open a channel between two source/drain electrodes. The transistor has the structures described above.

The methods, systems, and devices of the present disclosure are further illustrated in the following non-limiting working examples, it being understood that they are intended to be illustrative only and that the disclosure is not intended to be limited to the materials, conditions, process parameters and the like recited herein.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a transistor, comprising:
forming isolation regions in a substrate on opposite sides of an active region;
forming a gate dielectric layer between the isolation regions in the active region;
forming a gate electrode over the gate dielectric layer that comprises one or more first regions with a first work function and one or more second regions with a second opposite work function; and
forming source/drain (S/D) electrodes on opposite sides of the gate dielectric layer in the active region.

2. The method of claim 1, wherein the gate electrode is formed by:
forming a gate precursor layer;
doping the one or more first regions with a first dopant type; and
doping the one or more second regions with a second opposite dopant type.

3. The method of claim 1, wherein the one or more first regions together have a greater area than the one or more second regions together.

4. The method of claim 3, wherein the first work function is an n-type work function and the second work function is a p-type work function.

5. The method of claim 3, wherein the first work function is a p-type work function and the second work function is an n-type work function.

6. The method of claim 1, wherein the substrate is a silicon substrate.

7. The method of claim 6, wherein the one or more first regions comprise an n-type dopant comprising N, P, As, Bi, or Ta.

8. The method of claim 6, wherein the one or more second regions comprise a p-type dopant comprising B, Al, Ga, or In.

9. The method of claim 1, wherein the one or more second regions are located over the isolation regions and the active region.

10. The method of claim 1, wherein the isolation regions are shallow trench isolation (STI) regions or deep trench isolation (DTI) regions.

11. The method of claim 1, wherein the isolation regions and the gate dielectric layer are concurrently formed in a LOCal Oxidation of Silicon (LOCOS) operation.

12. The method of claim 1, wherein the gate electrode extends partially over at least one of the isolation regions.

13. The method of claim 1, wherein the substrate comprises gallium or cadmium.

14. The method of claim 13, wherein the one or more first regions and the one or more second regions each a dopant selected from the group consisting of Sn, Ti, Si, O, S, Se, Te, F, Cl, Br, I, Al, P, and Ga.

15. The method of claim 1, further comprising:
forming a first insulating layer over the substrate;
etching openings through the first insulating layer to the S/D electrodes and the gate electrode; and
filling the openings with an electrically conductive material to form at least one source via, at least one drain via, and at least one gate via.

16. The method of claim 15, further comprising:
forming a second insulating layer over the first insulating layer;
etching the second insulating layer to form pads over the at least one source via, at least one drain via, and at least one gate via; and
filling the pads with an electrically conductive material to form a source terminal, a drain terminal, and a gate terminal.

17. A transistor, comprising:
a substrate with one or more active regions extending between two S/D electrodes;
isolation regions on opposite sides of the active region;
a gate dielectric layer over the one or more active region between the two S/D electrodes; and
a gate electrode over the gate dielectric layer;
wherein the gate electrode comprises one or more first regions with a first work function and one or more second regions with a second opposite work function.

18. The transistor of claim 17, wherein the transistor is a planar transistor, a fin field effect transistor, or a gate-all-around transistor.

19. A method for operating a transistor, comprising:
changing a voltage signal to a gate electrode to open a channel between two source/drain electrodes;
wherein the gate electrode that comprises one or more first regions with a first work function and one or more second regions with a second opposite work function, wherein the one or more first regions and the one or more second regions are located over corners formed between isolation regions and an active region.

20. The method of claim 19, wherein the first work function is an n-type work function and the second work function is a p-type work function; or
wherein the first work function is a p-type work function and the second work function is an n-type work function.
